(19) United States
(12) Patent Application Publication
(10) Pub. No.: US 2013/0009515 A1
(43) Pub. Date: Jan. 10, 2013

(54) CONDUCTIVE PASTE COMPOSITION FOR INTERNAL ELECTRODES AND MULTILAYER CERAMIC ELECTRONIC COMPONENT INCLUDING THE SAME

(75) Inventors: Jong Han KIM, Suwon (KR); Young Ho Kim, Suwon (KR); Hyun Chul Jeong, Yongin (KR)

(73) Assignee: SAMSUNG ELECTRO-MECHANICS CO., LTD.

(21) Appl. No.: 13/292,828

(22) Filed: Nov. 9, 2011

(30) Foreign Application Priority Data
Jul. 7, 2011 (KR) 10-2011-0067438

(51) Int. Cl. H01L 41/00; H01F 5/00; H01C 7/10; H01B 1/08; H01B 1/02; H01C 7/13; H01G 4/12; B82Y 99/00

(52) U.S. Cl. 310/311; 338/22 R; 336/200; 361/321.2; 338/21; 252/512; 252/513; 977/773

(57) ABSTRACT

There are provided a conductive paste composition for an internal electrode and a multilayer ceramic electronic component including the same. The conductive paste composition includes: 100 moles of a metal powder; 0.5 to 4.0 moles of a ceramic powder; and 0.03 to 0.1 mole of a silica (SiO₂) powder. The conductive paste composition can raise the sintering shrinkage temperature of the internal electrodes and improve the connectivity of the internal electrodes, and can improve the degree of densification of the dielectric layer, thereby improving withstand voltage characteristics, reliability, and dielectric characteristics.

### CROSS-REFERENCE TO RELATED APPLICATIONS

This application claims the priority of Korean Patent Application No. 10-2011-0067438 filed on Jul. 7, 2011, in the Korean Intellectual Property Office, the disclosure of which is incorporated herein by reference.

### BACKGROUND OF THE INVENTION

1. Field of the Invention

The present invention relates to a conductive paste composition for internal electrodes and a multilayer ceramic electronic component including the same, and more particularly, to a conductive paste composition for internal electrodes, capable of controlling sintering shrinkage of a metal powder and a multilayer ceramic electronic component including the same.

2. Description of the Related Art

In general, electronic components using ceramic materials, such as capacitors, inductors, piezoelectric devices, varistors, or thermistors, include a ceramic sintered body made of ceramic materials, internal electrode layers formed inside the ceramic sintered body, and external electrodes formed on the surfaces of the ceramic sintered body to be connected to the internal electrode layers.

A multilayer ceramic capacitor (hereinafter, also referred to as “MLCC”) among ceramic electronic components includes a plurality of laminated dielectric layers, internal electrode layers disposed to oppose each other in which each pair of internal electrodes has one of the dielectric layers interposed therebetween, and external electrodes electrically connected to the internal electrodes.

The MLCC provides the advantages of compactness, high capacitance, and ease of mounting, so it is therefore used extensively in mobile communications devices such as notebook computers, PDAs, and cellular phones.

Recently, with the tendency for high performance, and lightweight, thin, short, and small element structures in the electric and electronic industries, electronic components have been required to be small as well as have high performance and a low price. Particularly, as improvements in the speed of CPUs, reductions in the size and weight of devices, and the digitalization and high functionality of devices are progressing, research into an MLCC having a small overall size, reduced thickness, high capacity and low impedance in a high frequency region is actively ongoing.

The MLCC may be manufactured by laminating a conductive paste for the internal electrodes and ceramic green sheets through a sheet method or a printing method, and then performing co-firing. However, in order to form dielectric layers, the ceramic green sheets may be fired at a temperature of 1100° C. or higher, and the conductive paste may undergo sintering shrinkage at a lower temperature. Therefore, the internal electrode layers may be over-sintered during the sintering of the ceramic green sheets, and as a result, the internal electrode layers may agglomerate or be separated, and the connectivity thereof may be deteriorated.

### SUMMARY OF THE INVENTION

An aspect of the present invention provides a conductive paste composition for internal electrodes, capable of controlling sintering shrinkage of a metal powder and a multilayer ceramic electronic component including the same.

According to an aspect of the present invention, there is provided a conductive paste composition for internal electrodes of a multilayer ceramic electronic component, the conductive paste composition including: 100 moles of a metal powder; 0.5 to 4.0 moles of a ceramic powder; and 0.03 to 0.1 mole of a silica (SiO₂) powder.

The metal powder may be at least one selected from the group consisting of Ni, Mn, Cr, Co, Al, and alloys thereof.

The metal powder may have an average grain diameter of 50 to 400 nm.

The ceramic powder may have an average grain diameter of 10 to 150 nm.

A ratio of an average grain diameter of the silica powder to an average grain diameter of the ceramic powder may be 1:4 to 1:6.

According to an aspect of the present invention, there is provided a multilayer ceramic electronic component, including: a ceramic sintered body: and an internal electrode layer formed inside the ceramic sintered body and having sintered ceramic grains or sintered silica grains trapped therein.

The sintered ceramic grains or the sintered silica grains may be trapped on an interface of metal grains for forming the internal electrode layer.

The internal electrode layer may be formed by using a conductive paste including 100 moles of a metal powder, 0.5 to 4.0 moles of a ceramic powder, and 0.03 to 0.1 mole of a silica (SiO₂) powder.

The internal electrode layer may include at least one metal selected from the group consisting of Ni, Mn, Cr, Co, Al, and alloys thereof.

The sintered ceramic grain may have an average grain diameter of 10 to 150 nm.

A ratio of an average grain diameter of the sintered silica grain to an average grain diameter of the sintered ceramic grain may be 1:4 to 1:6.

The ceramic sintered body and the internal electrode layer may be co-fired.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic perspective view of a multilayer ceramic capacitor according to an embodiment of the present invention;

FIG. 2 is a schematic cross-sectional view of the multilayer ceramic capacitor taken along line A-A′ of FIG. 1;

FIG. 3 is a schematic partial enlarged view of an internal electrode layer according to an embodiment of the present invention; and

FIGS. 4A through 4C are mimetic diagrams schematically showing sintering shrinkage behavior of a conductive paste for internal electrodes according to an embodiment of the present invention.

### DETAILED DESCRIPTION OF THE PREFERRED EMBODIMENT

Hereafter, embodiments of the present invention will be described in detail with reference to the accompanying drawings. The invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the shapes and dimensions may be exaggerated for clarity, and the same reference numerals will be used throughout to designate the same or like components.

The invention relates to ceramic electronic components. The electronic components using ceramic materials may be capacitors, inductors, piezoelectric devices, varistors, or thermistors. Hereinafter, a multi-layer chip capacitor (hereinafter, also referred to as “MLCC”) will be described as an example of the electronic components.

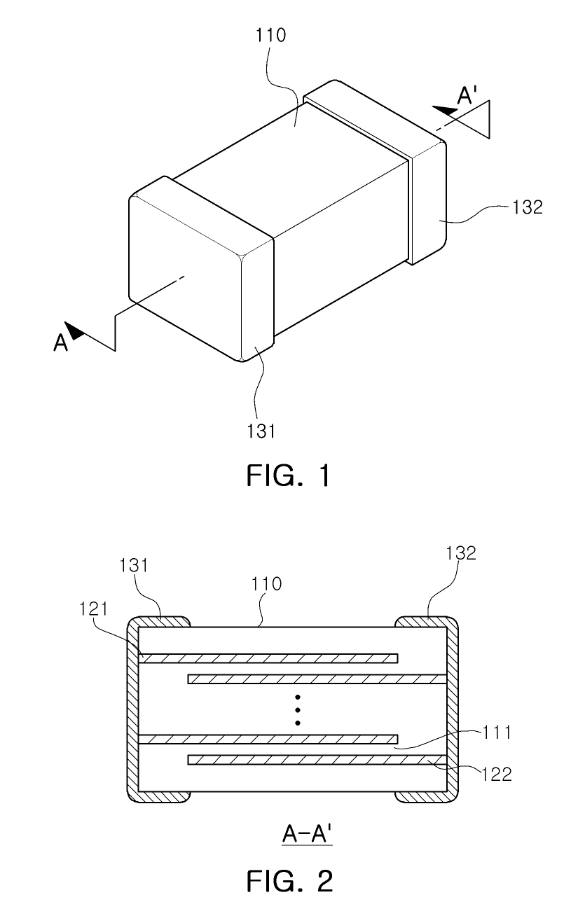

FIG. 1 is a schematic perspective view of a multilayer ceramic capacitor according to an embodiment of the present invention; and FIG. 2 is a schematic cross-sectional view of the multilayer ceramic capacitor taken along line I-I′ of FIG. 1.

Referring to FIGS. 1 and 2, a multilayer ceramic capacitor according to an embodiment of the present invention may include a ceramic sintered body 110, internal electrode layers 121 and 122 formed inside the ceramic sintered body, and external electrodes 131 and 132 formed on an external surface of the ceramic sintered body 110.

The shape of the ceramic sintered body 110 is not particularly limited, but may generally be a rectangular parallelepiped. In addition, dimensions of the ceramic sintered body are not particularly limited, but may have a size of, for example, 0.6 mm×0.3 mm. The ceramic sintered body 110 may be for a high lamination and high capacity multilayer ceramic capacitor of 2.2 μF or more.

The ceramic sintered body 110 may be formed by laminating a plurality of dielectric layers 111. The plurality of dielectric layers 111 constituting the ceramic sintered body 110 are in a sintered state, and the adjacent ceramic dielectric layers are integrated to the extent that a boundary cannot be readily discerned.

The dielectric layers 111 may be formed by sintering ceramic green sheets including a ceramic powder.

Any ceramic powder that may be generally used in the art may be used without particular limitations. The ceramic powder may include, but is not limited to, for example, a BaTiO₃ based ceramic powder. The BaTiO₃ based ceramic powder may be, but is not limited to, for example, (Ba₁₋ₓCaₓ) TiO₃, Ba (Ti_{1-y}Ca_{y}) O₃, (Ba₁₋ₓCaₓ) (Ti_{1-y}Zr_{y}) O₃, or Ba (Ti_{1-y}Zr_{y}) O₃, in which Ca, Zr, or the like is partially dissolved in BaTiO₃. An average grain diameter of the ceramic powder may be, but is not limited to, for example, 1.0 μm or less.

In addition, the ceramic green sheet may include a transition metal, a rare earth element, Mg, Al, or the like, together with the ceramic powder.

The ceramic green sheet may include a sintering additive of a glass component in order to lower a sintering temperature thereof. The sintering additive including the glass component is not particularly limited, and any sintering additive that is a glass component normally used in the art may be used. The sintering additive may be, but is not limited to, for example, a silicon dioxide-based glass component containing B, Ba, Ca Al, Li, or the like.

The thickness of the dielectric layer 111 may be appropriately changed depending on the desired capacitance of the multilayer ceramic capacitor. The thickness of the dielectric layer 111 formed between the adjacent internal electrode layers 121 and 122 after sintering may be, but is not limited to, 1.0 μm or less.

The internal electrode layers 121 and 122 may be formed inside the ceramic sintered body 110. The internal electrode layers 121 and 122 may be interleaved with the dielectric layer during the process of laminating the plurality of dielectric layers. The internal electrode layers 121 and 122 may be formed inside the ceramic sintered body 110 by sintering, with the dielectric layer interposed therebetween.

As for the internal electrode layers, a first internal electrode layer 121 and a second internal electrode layer 122, may be a pair of electrodes having different polarities, and may be disposed to oppose each other in a laminating direction of the dielectric layers. Ends of the first and second internal electrode layers 121 and 122 may be alternately and respectively exposed to both ends of the ceramic sintered body 110.

The thickness of each of the internal electrode layers 121 and 122 may be appropriately determined depending on the intended uses thereof, or the like. The thickness thereof may be, for example, 1.0 μm or less, or may be selected from within the range of 0.1 to 1.0 μm.

The internal electrode layers 121 and 122 may be formed by using a conductive paste for internal electrodes according to an embodiment of the present invention. The conductive paste for internal electrodes according to an embodiment of the present invention may include a metal powder, a ceramic powder, and a silica (SiO₂) powder. A detailed description thereof will be described later.

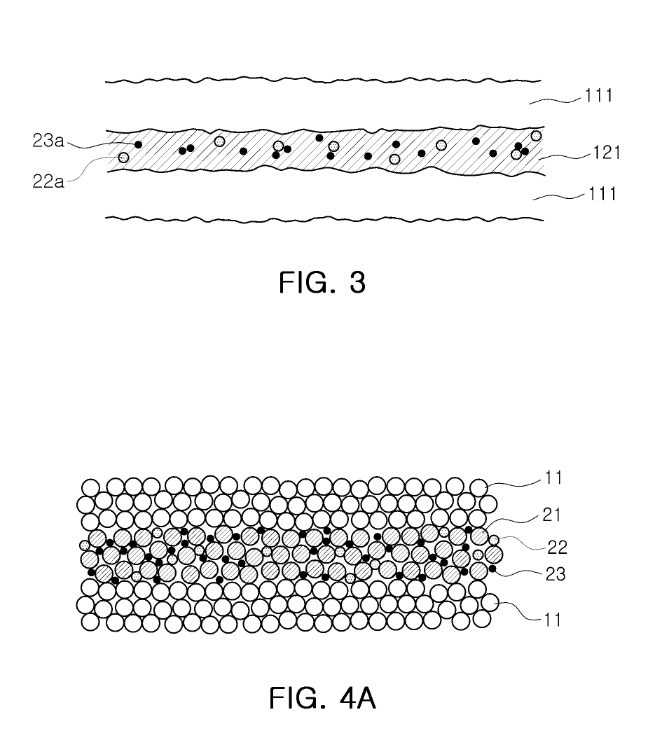

FIG. 3 is a partially enlarged view of the internal electrode layer 121 according to an embodiment of the present invention. Referring to FIG. 3, the internal electrode layer 121 may include sintered ceramic grains 22a and sintered silica grains 23a trapped therein. According to the embodiment of the present invention, both the sintered ceramic grains 22a and the sintered silica grains 23a are trapped in the internal electrode layer 121; however, without being limited thereto, only one of the sintered ceramic grains 22a and the sintered silica grains 23a may be included in the internal electrode layer 121.

The sintered ceramic grains 22a and the sintered silica grains 23a may be trapped on interfaces between metal grains constituting the internal electrode layer, that is, grain boundaries. The sintered ceramic grains 22a and the sintered silica grains 23a may be trapped on the interfaces of the metal grains, during the sintering of the metal powder for forming the internal electrode layers. This will be clarified by the conductive paste composition for the internal electrode and a forming procedure of the internal electrode layer to be described below.

According to an embodiment of the present invention, the external electrodes 131 and 132 may be formed on an external surface of the ceramic sintered body 110, and the external electrodes 131 and 132 may be electrically connected to the internal electrode layers 121 and 122. More specifically, the first internal electrode layer 121 exposed to one surface of the ceramic sintered body 110 may be electrically connected to a first external electrode 131, and the second internal electrode layer 122 exposed to the other surface of the ceramic sintered body 110 may be electrically connected to a second external electrode 132.

Although not shown, the first and second internal electrode layers may be exposed to at least one surface of the ceramic sintered body. Also, the first and second internal electrode layers may be exposed to the same surface of the ceramic sintered body.

The external electrodes 131 and 132 may be formed of a conductive paste including a conductive material. The conductive material included in the conductive paste may include, but is not particularly limited to, for example, Ni, Cu, or an alloy thereof. The thickness of the external electrodes 131 and 132 may be appropriately determined depending on the intended uses thereof, or the like, and may be, for example, about 10 to 50 μm.

Hereinafter, a conductive paste composition for internal electrodes of a multilayer ceramic electronic component according to an embodiment of the present invention will be described.

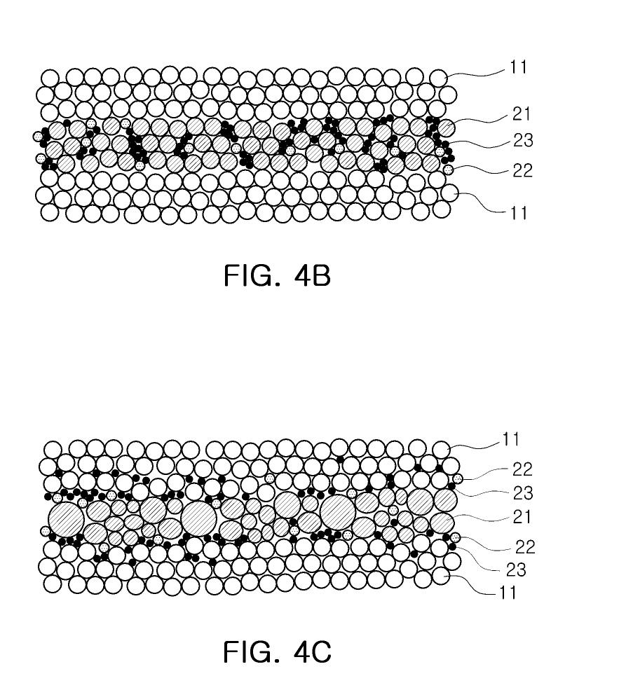

FIGS. 4A through 4C are mimetic diagrams schematically showing sintering shrinkage behavior of a conductive paste for internal electrodes according to an embodiment of the present invention.

A conductive paste composition for internal electrodes according to the embodiment of the present invention may include a metal powder 21, a ceramic powder 22, and a silica (SiO₂) powder 23.

The conductive paste composition for internal electrodes according to the embodiment of the present invention can raise a sintering shrinkage temperature of the internal electrode and improve the connectivity of the internal electrodes. In addition, the conductive paste composition can improve the degree of densification of the dielectric layers, thereby improving withstand voltage characteristics, reliability, and dielectric characteristics.

Types of the meal powder 21 included in the conductive paste composition are not particularly limited, and for example, a base metal may be used for the metal powder 21. Examples of the metal powder may include, but are not limited to, for example, at least one of Ni, Mn, Cr, Co, Al or alloys thereof.

An average grain diameter of the meal powder 21 is not particularly limited, but may be 400 nm or less. More specifically, the average grain diameter of the metal powder 21 may be 50 to 400 nm.

The ceramic powder 22 included in the conductive paste composition may include the same components as those of a ceramic powder 11 for forming the dielectric layer. The ceramic powder may include, but is not limited to, for example, a BaTiO₃ based ceramic powder. The BaTiO₃ based ceramic powder may include, but is not limited to, for example, (Ba₁₋ₓCaₓ) TiO₃, Ba (Ti_{1-y}Ca_{y}) O₃, (Ba₁₋ₓCaₓ) (Ti_{1-y}Zr_{y}) O₃, or Ba (Ti_{1-y}Zr_{y}) O₃, in which Ca, Zr, or the like is partially dissolved in BaTiO₃.

The ceramic powder 22 may have a smaller average grain diameter than the metal powder 21. The average grain diameter of the ceramic powder 22 may also be smaller than that of the ceramic powder 11 for forming the dielectric layer.

The ceramic powder 22 may have an average grain diameter of 10 to 150 nm, without being limited thereto. Since the ceramic powder 22 having a smaller average grain diameter than the metal powder 21 is used, the ceramic powder 22 may be distributed between the grains of the metal powder 21.

The ceramic powder 22 can raise the sintering shrinkage-initiation temperature of the metal powder 21, and suppress the sintering shrinkage of the metal powder 21. More specifically, the ceramic powder 22 can prevent contact between metal powder grains at the time of the sintering shrinkage of the metal powder 21, thereby suppressing grain growth of the metal powder.

According to the embodiment of the present invention, the content of the ceramic powder 22 may be 0.5 to 4.0 moles, based on 100 moles of the metal powder 21. If the content of the ceramic powder 22 is below 0.5 mole, it is difficult to effectively suppress the sintering of the metal powder, and thus, the connectivity of the electrodes may be deteriorated. Whereas, if the content of the ceramic powder 22 is above 0.4 mole, the amount of the ceramic powder moving to the dielectric layer during the sintering of the internal electrode layer is increased, and thus, the connectivity of the electrodes may be deteriorated.

The silica powder (SiO₂) 23 included in the conductive paste composition is crystalline, and may have a higher melting point than the metal powder 21. The melting point of the silica powder 23 may be, but is not limited to, 1100□ or higher. The silica powder 23 may have a smaller average grain diameter than the metal powder 21 and the ceramic powder 22. The average grain diameter of the silica powder 23 may also be smaller than the average grain diameter of the ceramic powder 11 for forming the dielectric layer. A ratio of the average grain diameter of the silica powder 23 to the average grain diameter of the ceramic powder 22 may be, but is not limited to, 1:4 to 1:6. Since the silica powder 23 having a smaller average grain diameter than the metal powder 21 and the ceramic powder 22 is used, the silica powder 23 may be distributed between the grains of the metal powder 21 and the ceramic powder 22.

The silica powder 23 can raise the sintering shrinkage-initiation temperature of the metal powder 21, and suppress the sintering shrinkage of the metal powder 21. More specifically, the silica powder 23 can prevent contact between the metal powder grains at the time of the sintering shrinkage of the metal powder 21 together with the ceramic powder 22, thereby suppressing grain growth of the metal powder.

According to an embodiment of the present invention, the content of the silica powder 23 may be 0.03 to 0.1 mole, based on 100 moles of the metal powder 21. If the content of the silica powder 23 is below 0.03 mole, it is difficult to effectively suppress the sintering of the metal powder, and thus, electrode connectivity may be deteriorated. Whereas, if the content of the silica powder 23 is above 0.1 mole, grain overgrowth may occur in the dielectric layer.

The conductive paste composition for internal electrodes according to an embodiment of the present invention may additionally include a dispersant, a binder, a solvent, or the like.

Examples of the binder may include, but are not limited to, polyvinyl butyral, a cellulose-based resin, or the like. The polyvinyl butyral has a strong adhesive strength, and thus, can enhance the adhesive strength between the conductive paste for internal electrodes and the ceramic green sheet.

The cellulose-based resin has a chair-type structure, and an elastic recovery thereof is rapid when transformation occurs. The inclusion of the cellulose-based resin allows a flat print surface to be secured.

Examples of the solvent may include, but are not particularly limited to, for example, butyl carbitol, kerosene, or terpineol-based solvent. Examples of the terpineol-based solvent may be, but are not particularly limited to, dehydro terpineol, dihydro terpinyl acetate, or the like.

In general, the paste composition for internal electrodes is printed on the ceramic green sheet, followed by procedures, such as lamination and the like, and then may be co-fired together with the ceramic green sheet.

Meanwhile, in the case in which the base metal is used for the internal electrode layers, the internal electrode layers may be oxidized when being fired under the atmosphere. Therefore, the co-firing of the ceramic green sheet and the internal electrode layer may be performed under a reductive atmosphere.

The dielectric layer of the multilayer ceramic capacitor may be formed by firing the ceramic green sheet at a high temperature of about 1100° C. or higher. In the case in which the base metal, such as Ni or the like, is used for the internal electrode layer, the internal electrode layer may undergo sintering shrinkage while oxidation occurs from a low temperature of 400° C., and be rapidly sintered at a temperature of 1000° C. or higher. When the internal electrode layer is rapidly sintered, the internal electrode layer may agglomerate or be broken due to the over-sintering thereof, and the connectivity and capacity of the internal electrode layer may be deteriorated. Further, after firing, the multilayer ceramic capacitor may have a defective inner structure such as cracks.

Therefore, the sintering-initiation temperature of the metal powder, at which sintering starts at a relatively low temperature of 400 to 500° C., needs to be raised to the maximum limit, to minimize a shrinkage difference between the internal electrode layer and the dielectric layer.

FIGS. 4A through 4C are mimetic diagrams schematically showing sintering shrinkage behavior of a conductive paste for internal electrodes according to an embodiment of the present invention.

With reference to FIGS. 4A through 4C, the ceramic powder 11 may be formed into the dielectric layer 111 shown in FIG. 2 through the sintering procedure.

As shown in FIG. 4A, the metal powder 21, the ceramic powder 22, and the silica powder 23 are uniformly dispersed at an initial stage of a firing process. As shown in FIG. 4B, as the temperature rises, the metal powder 21 may agglomerate to start necking between the grains of the metal powder. Then, as shown in FIG. 4C, as the necking between the grains of the metal powder starts, the ceramic powder 22 and the silica powder 23 may escape from the metal powder 21 and move toward the ceramic powder 11 for forming the dielectric layer.

The ceramic powder 22 moving from the metal powder 21 may have a smaller average grain diameter than the ceramic powder 11 for forming the dielectric layer. Accordingly, the ceramic powder 22 may start to be sintered at a temperature lower than a sintering temperature of the ceramic powder 11 for forming the dielectric layer. Therefore, the ceramic powder 22 may react with a sintering additive present in the ceramic powder 11 for forming the dielectric layer, thereby initiating the sintering thereof. Meanwhile, when the ceramic powder 11 for forming the dielectric layer starts to be sintered, a portion of the dielectric layer close to the internal electrode layer may be relatively lacking in the sintering additive as compared with the other portions thereof, resulting in the non-uniform sintering of the dielectric layer.

However, according to an embodiment of the present invention, the silica powder 23 is used in the sintering of the ceramic powders 11 and 22, and thus, the entire dielectric layer can be uniformly sintered. As such, as the sintering uniformity of the dielectric layer is improved, dielectric characteristics, withstand voltage characteristics, reliability, or the like can be improved.

The sintered ceramic grains 22a trapped in the internal electrode layer 121 may be configured such that the ceramic powder 22 is directly trapped in the internal electrode layer 121 or in which the ceramic powder 22 agglomerates or some of the ceramic powder 22 is sintered during the sintering process of the conductive paste for internal electrodes.

The sintered silica grains 23a trapped in the internal electrode layer 121 may be configured such that the silica powder 23 is directly trapped in the internal electrode layer 121 or in which the silica powder 23 agglomerates or some of the silica powder 23 is sintered during the sintering process of the conductive paste for internal electrodes.

In general, the metal powder is sintered to form the internal electrode layer before the ceramic powder 11 for forming the dielectric layer is shrunken, and the internal electrode layer may agglomerate while the ceramic powder 11 for forming the dielectric layer is shrunken, thereby deteriorating the connectivity of the internal electrode.

However, as described above, according to the embodiment of the present invention, the ceramic powder 22 and the silica powder 23 are well dispersed in the metal powder 21, and thus, the sintering of the metal powder may be suppressed up to a temperature of 1000° C. or higher.

The sintering of the ceramic powder 11 may be initiated while the sintering of the metal powder 21 is maximally suppressed up to a temperature of about 1000° C. When densification of the ceramic powder 11 for forming the dielectric layer is initiated, densification of the internal electrode layer also starts and sintering may proceed promptly. Here, when a temperature increase rate is regulated, the ceramic powder 22 and the silica powder 23 cannot escape from the metal powder 21, and may be trapped on the grain boundary of the metal powder 21 in the form of the sintered ceramic grains 22a and the sintered silica grains 23a, as shown in FIG. 3. Therefore, the agglomeration of the internal electrode layer can be suppressed, thereby increasing connectivity of the internal electrode layer.

Recently, as the multilayer ceramic capacitor has become smaller and lighter, the dielectric layer and the internal electrode layer have become thinner. More fine-grain powder may be used in order to form a thin-type dielectric layer and a thin-type internal electrode layer, but it is difficult to control the sintering shrinkage of the ceramic powder and the metal powder. However, according to an embodiment of the present invention, since the ceramic powder and the silica powder are included in the conductive paste for the internal electrode, the sintering shrinkage of the metal powder can be suppressed and the dielectric layer can be uniformly sintered. In addition, the ceramic powder and the silica powder are trapped in the internal electrode layer, resulting in an improvement in the connectivity of the internal electrode layer, and thus, the internal electrode layer can be thinner.

Hereinafter, a method of manufacturing a multilayer ceramic capacitor according to an embodiment of the present invention will be described.

A plurality of ceramic green sheets may be prepared. The ceramic green sheets may be prepared as sheets having a thickness of several micrometers by mixing a ceramic powder, a binder, a solvent, and the like to prepare a slurry and subsequently performing a doctor blade method on the slurry. The ceramic green sheets may be then sintered, thereby forming the dielectric layers 111 shown in FIG. 2.

Then, a conductive paste for internal electrodes may be coated on the ceramic green sheets to form internal electrode patterns. The internal electrode patterns may be formed by a screen printing method or a gravure printing method.

The conductive paste composition for internal electrodes according to an embodiment of the present invention may be used, and specific components and contents thereof are described as above.

Then, the plurality of ceramic green sheets are laminated and pressed in a laminating direction, and the laminated ceramic green sheets and the paste for the internal electrode layers are compressed with each other. Thus, a ceramic laminate, in which the ceramic green sheets and the paste for the internal electrode layers are alternately laminated, may be manufactured.

Then, the ceramic laminate may be cut into respective regions corresponding to each capacitor and be formed as chips. Here, the cutting may be performed such that ends of internal electrode patterns are alternately exposed through end surfaces of the capacitor. Then, the ceramic laminate formed as a chip may be fired to manufacture a ceramic sintered body. As described above, the firing process may be performed under a reductive atmosphere. In addition, the firing process may be performed through the regulation of the temperature increase rate. The temperature increase rate may be, but is not limited to, 30° C./60 s to 50° C./60 s.

Then, external electrodes may be formed to cover end surfaces of the ceramic sintered body. The external electrodes may be electrically connected to the internal electrode layers exposed to the end surfaces of the ceramic sintered body. Then, a plating treatment may be performed on surfaces of the external electrodes using nickel, tin, or the like.

As described above, the sintered ceramic grains 22a and the sintered silica grains 23a may be trapped on the grain boundary of the internal electrode layer 121, and as a result, the connectivity of the internal electrode layer may be improved. In addition, the dielectric layer 111 may be uniformly sintered by the silica powder 23.

A conductive paste composition for internal electrodes according to an embodiment of the present invention was prepared and then a multilayer ceramic capacitor was manufactured using the same. More specifically, the conductive paste was prepared by mixing a nickel powder, barium titanate (BaTiO₃) and a silica powder. The nickel powder (metal powder) had a content of 50 wt %, based on the conductive paste, and the content of the barium titanate (ceramic powder) and the content of the silica powder, are shown in Table 1.

### [Evaluation]

An electrode connectivity of the multilayer ceramic capacitor was defined as a value by calculating a ratio of a length of an internal electrode layer excluding pores based on a total length of the internal electrode layer, in one section of the internal electrode layer, and evaluated according to the following standard. The results were tabulated in Table 1.

⊚: very good (electrode connectivity of 85% or greater)

∘: good (electrode connectivity of 75% or greater and less than 85%)

x: poor (electrode connectivity of less than 75%)

TABLE 1

| | BaTiO₃ | SiO₂ Powder | Electrode |
|---|---|---|---|
| | (mol %/Ni) | (mol %/Ni) | Connectivity (%) |
| Comparative example 1 | 0.3 | 0.03 | x |
| Comparative example 2 | 0.3 | 0.05 | x |
| Example 1 | 0.5 | 0.03 | □ |
| Example 2 | 0.5 | 0.1 | ∘ |
| Example 3 | 0.5 | 0.1 | ∘ |
| Comparative example 3 | 0.5 | 0.12 | x |
| Example 4 | 1.0 | 0.03 | □ |
| Example 5 | 1.0 | 0.1 | □ |
| Comparative example 4 | 1.0 | 0.1 | x |
| Comparative example 5 | 1.0 | 0.12 | x |
| Example 6 | 3.0 | 0.05 | □ |
| Example 7 | 3.0 | 0.1 | □ |
| Example 8 | 3.0 | 0.07 | ∘ |
| Comparative example 6 | 3.0 | 0.12 | x |
| Example 9 | 4.0 | 0.05 | □ |
| Example 10 | 4.0 | 0.07 | □ |
| Example 11 | 4.0 | 0.1 | ∘ |
| Comparative example 7 | 4.0 | 0.15 | x |

Referring to Table 1, in Examples 1 to 11, 75% or more of electrode connectivity could be secured by regulating the contents of the ceramic powder (BaTiO₃) and the silica powder (SiO₂).

Whereas, in Comparative Examples 1 to 7, 75% or more of electrode connectivity could not be secured due to excessive or insufficient amounts of the ceramic powder (BaTiO₃) and the silica powder (SiO₂). For this reason, Examples 1 to 11 according to embodiments of the present invention had excellent electrical characteristics as compared with Comparative examples 1 to 7.

As set forth above, a conductive paste composition for internal electrodes according to embodiments of the present invention may include a metal powder, a ceramic powder, and a silica (SiO₂) powder.

The conductive paste composition for internal electrodes according to embodiments of the present invention can raise a sintering shrinkage temperature of the internal electrodes and improve the connectivity of the internal electrodes. In addition, the conductive paste composition can improve the degree of densification of the dielectric layer, thereby improving withstand voltage characteristics, reliability, and dielectric characteristics.

In the conductive paste composition for internal electrodes according to embodiments of the present invention, the silica powder is used in the sintering of the ceramic powder, and thus, the entire dielectric layer can be uniformly sintered.

According to embodiments of the present invention, the ceramic powder or the silica powder can be trapped on the grain boundary of the internal electrode layer by regulating a temperature increase rate. Therefore, the agglomeration of the internal electrode layer can be suppressed, whereby the connectivity of the internal electrode layer can be increased.

According to embodiments of the present invention, since the ceramic powder and the silica powder are included in the conductive paste for internal electrodes, the sintering shrinkage of the metal powder can be suppressed and the dielectric layer can be uniformly sintered. In addition, the ceramic powder and the silica powder are trapped in the internal electrode layer, resulting in an improvement in the connectivity of the internal electrode layer, and thus, the internal electrode layer can be thinner.

While the present invention has been shown and described in connection with the embodiments, it will be apparent to those skilled in the art that modifications and variations can be made without departing from the spirit and scope of the invention as defined by the appended claims.

What is claimed is:

1. A conductive paste composition for internal electrodes of a multilayer ceramic electronic component, the conductive paste composition comprising:
100 moles of a metal powder;
0.5 to 4.0 moles of a ceramic powder; and
0.03 to 0.1 mole of a silica (SiO₂) powder.

2. The conductive paste composition of claim 1, wherein the metal powder is at least one selected from the group consisting of Ni, Mn, Cr, Co, Al, and alloys thereof.

3. The conductive paste composition of claim 1, wherein the metal powder has an average grain diameter of 50 to 400 nm.

4. The conductive paste composition of claim 1, wherein the ceramic powder has an average grain diameter of 10 to 150 nm.

5. The conductive paste composition of claim 1, wherein a ratio of an average grain diameter of the silica powder to an average grain diameter of the ceramic powder is 1:4 to 1:6.

6. A multilayer ceramic electronic component, comprising:
a ceramic sintered body: and
an internal electrode layer formed inside the ceramic sintered body and having sintered ceramic grains or sintered silica grains trapped therein.

7. The multilayer ceramic electronic component of claim 6, Wherein the sintered ceramic grains or the sintered silica grains are trapped on an interface of metal grains for forming the internal electrode layer.

8. The multilayer ceramic electronic component of claim 6, wherein the internal electrode layer is formed by using a conductive paste including 100 moles of a metal powder, 0.5 to 4.0 moles of a ceramic powder, and 0.03 to 0.1 mole of a silica (SiO₂) powder.

9. The multilayer ceramic electronic component of claim 6, wherein the internal electrode layer includes at least one metal selected from the group consisting of Ni, Mn, Cr, Co, Al, and alloys thereof.

10. The multilayer ceramic electronic component of claim 6, wherein the sintered ceramic grain has an average grain diameter of 10 to 150 nm.

11. The multilayer ceramic electronic component of claim 6, wherein a ratio of an average grain diameter of the sintered silica grain to an average grain diameter of the sintered ceramic grain is 1:4 to 1:6.

12. The multilayer ceramic electronic component of claim 6, wherein the ceramic sintered body and the internal electrode layer are co-fired.
